(19) United States
(12) Patent Application Publication
(10) Pub. No.: US 2024/0096954 A1
(43) Pub. Date: Mar. 21, 2024

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Il Gyou SHIN, Suwon-si (KR); Hyun Ho NOH, Suwon-si (KR); Sang Yong KIM, Suwon-si (KR); You Bin KIM, Suwon-si (KR)

(73) Assignee: SAMSUNG ELECTRONICS CO., LTD., Suwon-si (KR)

(21) Appl. No.: 18/231,594

(22) Filed: Aug. 8, 2023

(30) Foreign Application Priority Data
Sep. 20, 2022 (KR) 10-2022-0118448

(51) Int. Cl. H01L 29/06; H01L 29/417; H01L 29/423; H01L 29/66; H01L 29/775; H01L 29/786

(52) U.S. Cl. CPC H01L 29/0673; H01L 29/41733; H01L 29/41775; H01L 29/42392; H01L 29/66439; H01L 29/66545; H01L 29/775; H01L 29/78696

(57) ABSTRACT

A semiconductor device includes an active pattern including: a lower pattern extending in a first direction, and a plurality of sheet patterns spaced apart from the lower pattern in a second direction; a gate structure on the lower pattern and including a gate electrode and a gate insulating film including an interfacial insulating film including a first vertical portion and a horizontal portion. A dimension in a third direction of the first vertical portion is greater than a dimension in the second direction of the horizontal portion. The first vertical portion includes: a first area contacting a source/drain pattern; and a second area provided between the first area and the gate electrode. The interfacial insulating film includes a first element other than silicon, wherein a concentration of the first element in the first area is greater than a concentration of the first element in the second area.

### CROSS-REFERENCE TO RELATED APPLICATION

This application claims priority from Korean Patent Application No. 10-2022-0118448 filed on Sep. 20, 2022 in the Korean Intellectual Property Office, the disclosure of which is incorporated by reference herein in its entirety.

### BACKGROUND

The present disclosure relates to a semiconductor device and a method for manufacturing the same, and more specifically, to a semiconductor device including a Multi-Bridge Channel Field Effect Transistor (MBCFET™) (and) a method for manufacturing the same.

One of scaling schemes for increasing a density of a semiconductor device includes a multi gate transistor in which a multi-channel active pattern (or silicon body) in a shape of a fin, or a nanowire, is formed on a substrate and a gate is formed on a surface of the multi-channel active pattern.

Because the multi-gate transistor uses a three-dimensional channel, it is easy to scale the multi-gate transistor. Further, current control ability of the multi-gate transistor may be improved without increasing a gate length of the multi-gate transistor. In addition, the multi-gate transistor may effectively suppress short channel effect (SCE) in which a potential of a channel area is affected by a drain voltage.

### SUMMARY

One or more example embodiments provide a semiconductor device capable of improving element performance and reliability and a method for manufacturing such a semiconductor device.

Additional aspects will be set forth in part in the description which follows and, in part, will be apparent from the description, or may be learned by practice of the presented embodiments.

According to an aspect of an example embodiment, a semiconductor device includes: an active pattern including: a lower pattern extending in a first direction; and a plurality of sheet patterns spaced apart from the lower pattern in a second direction perpendicular to an upper surface of the lower pattern, each of the plurality of sheet patterns including an upper surface and a lower surface opposite to each other in the second direction; a gate structure provided on the lower pattern, and including a gate electrode and a gate insulating film, wherein the gate electrode and the gate insulating film are around the plurality of sheet patterns; and a source/drain pattern provided on at least one side of the gate structure, wherein the gate structure includes a plurality of inter gate structures provided between the lower pattern and the plurality of sheet patterns and between adjacent sheet patterns of the plurality of sheet patterns, wherein the plurality of inter gate structures contact the source/drain pattern, wherein the gate insulating film includes an interfacial insulating film, wherein the interfacial insulating film includes: a first vertical portion extending along the source/drain pattern; and a horizontal portion extending along the upper surface of each of the plurality of sheet patterns, and along the lower surface of each of the plurality of sheet patterns, wherein a first dimension in a third direction of the first vertical portion of the interfacial insulating film is greater than a second dimension in the second direction of the horizontal portion of the interfacial insulating film, wherein the first vertical portion includes: a first area in contact with the source/drain pattern; and a second area provided between the first area and the gate electrode, wherein the interfacial insulating film includes a first element other than silicon, and wherein a first concentration of the first element in the first area is greater than a second concentration of the first element in the second area.

According to an aspect of an example embodiment, a semiconductor device includes: an active pattern including: a lower pattern extending in a first direction; and a plurality of sheet patterns spaced apart from the lower pattern in a second direction perpendicular to an upper surface of the lower pattern; a gate structure provided on the lower pattern and extending in a third direction perpendicular to the first direction, the gate structure including: a gate electrode around the plurality of sheet patterns; and a gate insulating film provided on the gate electrode, a plurality of gate spacers provided on the gate insulating film and spaced apart from each other in the third direction; and a source/drain pattern provided between the plurality of gate spacers and contacting each of the plurality of sheet patterns and the gate insulating film, wherein the gate insulating film includes an interfacial insulating film, wherein the interfacial insulating film includes: a first area contacting the source/drain pattern; and a second area provided between the first area and the gate electrode, wherein the interfacial insulating film includes a first element other than silicon, and wherein a first concentration of the first element in the first area is different from a second concentration of the first element in the second area.

According to an aspect of an example embodiment, a method for manufacturing a semiconductor device, includes: providing a substrate; forming, on the substrate, an upper pattern structure in which a plurality of sacrificial films and a plurality of active films are alternately stacked; forming a dummy gate electrode on the upper pattern structure; forming a source/drain recess in the upper pattern structure using the dummy gate electrode as a mask; etching a portion of each of the plurality of sacrificial films exposed by the source/drain recess; forming a source/drain pattern filling the source/drain recess; removing the plurality of sacrificial films to form a gate trench and a plurality of sheet patterns, wherein a portion of the source/drain pattern is exposed by the gate trench; performing a plasma processing process to form a growth area in the portion of the source/drain pattern exposed by the gate trench; and forming an interfacial insulating film in the gate trench, wherein the interfacial insulating film includes: a vertical portion contacting the source/drain pattern; and a horizontal portion extending along an upper surface of each of the plurality of sheet patterns and along a lower surface of the plurality of sheet patterns, and wherein a first dimension in a vertical direction of the vertical portion is greater than a second dimension in the vertical direction of the horizontal portion.

### BRIEF DESCRIPTION OF DRAWINGS

The above and other aspects and features of the present disclosure will become more apparent by describing in detail example embodiments thereof with reference to the attached drawings, in which:

FIG. 1 is an illustrative plan view for illustrating a semiconductor device according to one or more example embodiments.

FIG. 2 and FIG. 3 are cross-sectional views taken along a line A-A and a line B-B of FIG. 1, according to one or more example embodiments.

FIG. 4 is an enlarged view of an area P1 of FIG. 2, according to one or more example embodiments.

FIG. 5 is a diagram for illustrating a semiconductor device according to one or more example embodiments.

FIG. 6 is an enlarged view of an area Q of FIG. 3, according to one or more example embodiments.

FIG. 7 is a top view taken along a line C-C of FIG. 2, according to one or more example embodiments.

FIG. 8 is a diagram for illustrating a semiconductor device according to one or more example embodiments.

FIGS. 9 and 10 are diagrams for illustrating a semiconductor device according to one or more example embodiments.

FIG. 11 and FIG. 12 are diagrams for illustrating a semiconductor device according to one or more example embodiments.

FIGS. 13, 14, 15, 16, 17, 18, 19, 20 and 21 are diagrams of intermediate structures corresponding to intermediate steps for illustrating a method for manufacturing a semiconductor device according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

For simplicity and clarity of illustration, elements in the drawings are not necessarily drawn to scale. similar elements, and as such perform similar functionality. Further, descriptions and details of well-known steps and elements are omitted for simplicity of the description. Furthermore, in the following detailed description of one or more example embodiments, numerous specific details are set forth in order to provide a thorough understanding of one or more example embodiments. However, it will be understood that one or more example embodiments may be practiced without these specific details. In other instances, well-known methods, procedures, components, and circuits have not been described in detail to avoid unnecessarily obscuring aspects of one or more example embodiments. Examples of one or more example embodiments are illustrated and described further below. It will be understood that the description herein is not intended to limit the claims to the specific one or more example embodiments described. On the contrary, the description is intended to cover alternatives, modifications, and equivalents as may be included within the spirit and scope of one or more example embodiments as defined by the appended claims.

A shape, a size, a ratio, an angle, a number, etc. disclosed in the drawings for illustrating one or more example embodiments are illustrative, and one or more example embodiments are not limited thereto.

The terminology used herein is for the purpose of describing one or more example embodiments only and is not intended to limit one or more example embodiments. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expressions such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of one or more example embodiments.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which one or more example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain one or more example embodiments may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of one or more example embodiments may be partially or entirely combined with each other, and may be technically associated with each other or operate with each other. The one or more example embodiments may be implemented independently of each other and may be implemented together in an association relationship. Spatially relative terms, such as “beneath,” “below,” “lower,” “under,” “above,” “upper,” and the like, may be used herein for ease of explanation to describe a relationship of one element or feature to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Terms as used herein “first direction D1”, “second direction D2” and “third direction D3” should not be interpreted only to have a geometric relationship in which the first direction, the second direction, and the third direction are perpendicular to each other. The “first direction D1”, the “second direction D2” and the “third direction D3” may be interpreted to have a broader direction within a range in which components herein may work functionally.

The semiconductor device according to one or more example embodiments may include a tunneling transistor (tunneling Field Effect Transistor (FET)), a 3D transistor, or a 2D material-based FET based on a two-dimensional material, and a heterostructure thereof. Further, the semiconductor device according to one or more example embodiments may include a bipolar junction transistor, a lateral double diffusion transistor (LDMOS), and the like.

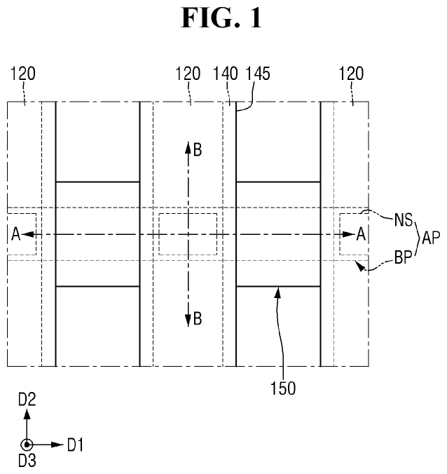

Referring to FIGS. 1, 2, 3, 4, 5, 6, 7 and 8, descriptions of a semiconductor device according to one or more example embodiments will be provided below.

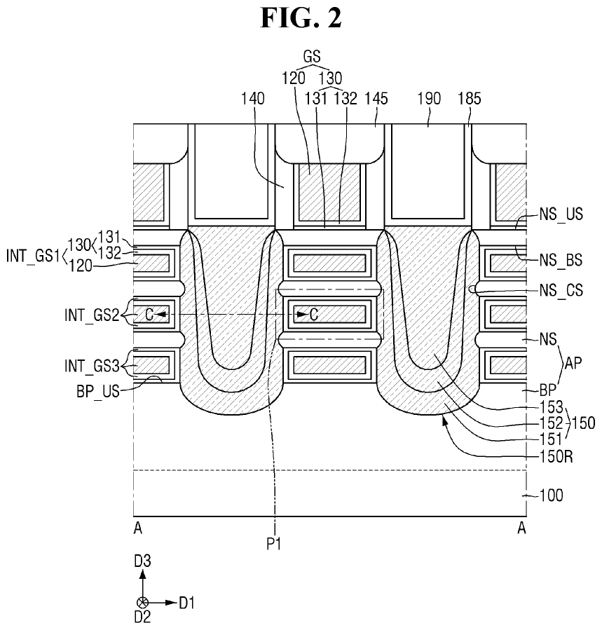

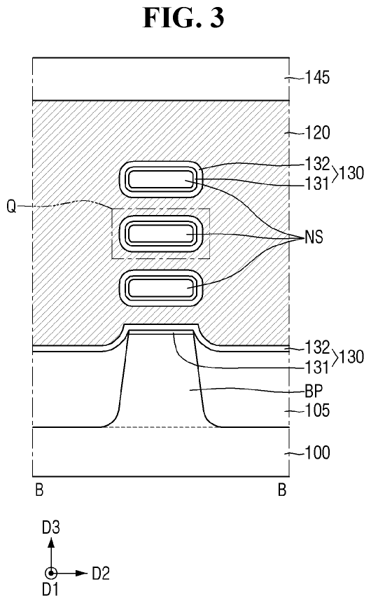

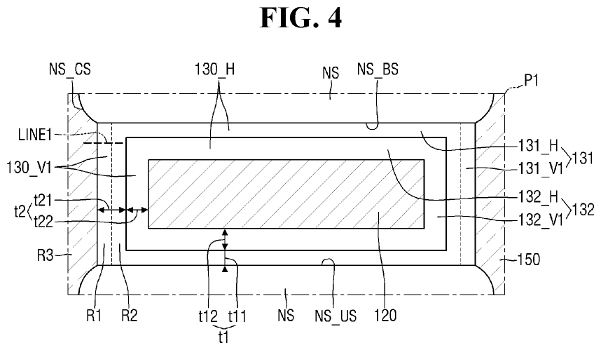

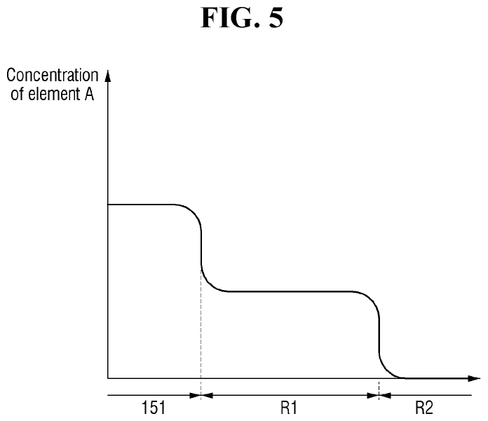

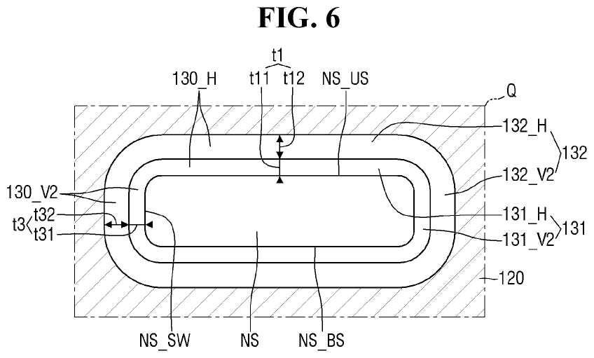

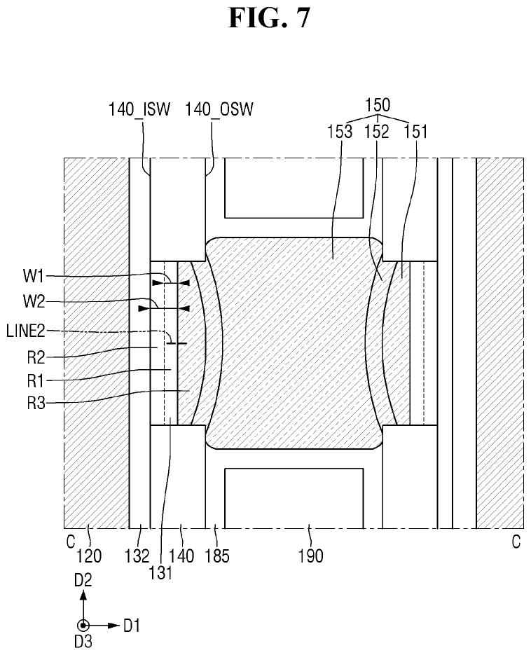

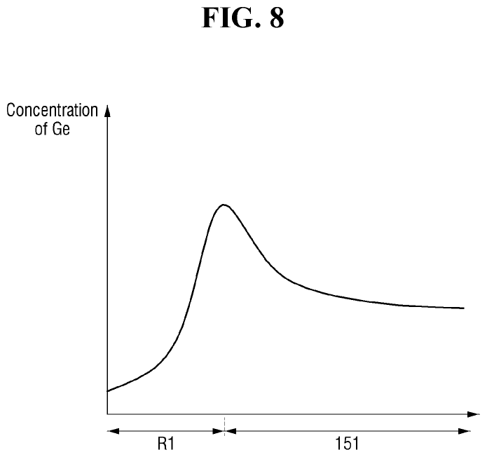

FIG. 1 is an illustrative plan view for illustrating a semiconductor device according to one or more example embodiments. FIG. 2 and FIG. 3 are cross-sectional views taken along a line A-A and a line B-B of FIG. 1, according to one or more example embodiments. FIG. 4 is an enlarged view of an area P1 of FIG. 2, according to one or more example embodiments. FIG. 5 is a diagram for illustrating a semiconductor device according to one or more example embodiments. FIG. 6 is an enlarged view of an area Q of FIG. 3, according to one or more example embodiments. FIG. 7 is a top view taken along a line C-C of FIG. 2, according to one or more example embodiments. FIG. 8 is a diagram for illustrating a semiconductor device according to one or more example embodiments.

For reference, FIG. 5 schematically shows a concentration of an element A along a LINE1 in FIG. 4, according to one or more example embodiments. FIG. 8 is a diagram schematically showing a concentration of germanium (Ge) along a LINE2 of FIG. 7, according to one or more example embodiments.

FIG. 2 schematically shows the semiconductor device comprising a gate insulating film 130, an etch stop film 185, and a interlayer insulating film 190.

Referring to FIGS. 1, 2, 3, 4, 5, 6, 7 and 8, the semiconductor device according to one or more example embodiments may include a substrate 100, an active pattern AP, a plurality of gate structures GS, and a source/drain pattern 150.

The substrate 100 may be made of bulk silicon or silicon-on-insulator (SOI). Alternatively, the substrate 100 may be embodied as a silicon substrate, or may be made of a material other than silicon, including, but not limited to, silicon germanium, silicon germanium on insulator (SGOI), indium antimonide, a lead telluride compound, indium arsenide, indium phosphide, gallium arsenide or gallium antimonide. However, one or more example embodiments are not limited thereto.

The active pattern AP may be disposed on the substrate 100. The active pattern AP may extend in an elongate manner in the first direction D1. For example, according to one or more example embodiments, the active pattern AP may be disposed in an area where a p-channel metal-oxide-semiconductor (PMOS) is formed. In another one or more example embodiments, the active pattern AP may be disposed in an area where an N-type metal-oxide-semiconductor (NMOS) is formed.

The active pattern AP may be embodied as a multi-channel active pattern. The active pattern AP may include a lower pattern BP and a plurality of sheet patterns NS. The lower pattern BP may protrude from the substrate 100. The lower pattern BP may extend in the first direction D1.

The plurality of sheet patterns NS may be disposed on a upper surface BP_US of the lower pattern. The plurality of sheet patterns NS may be spaced apart from the lower pattern BP in a third direction D3. The sheet patterns NS may be spaced apart from each other in the third direction D3.

Each of the sheet patterns NS may include a upper surface NS_US and a lower surface NS_BS. The upper surface NS_US of the sheet pattern is opposite to the lower surface NS_BS of the sheet pattern in the third direction D3. Each of the sheet patterns NS may include connection faces NS_CS opposite to each other in the first direction D1 and sidewalls NS_SW opposite to each other in the second direction D2.

The upper surface NS_US of the sheet pattern and the lower surface NS_BS of the sheet pattern may be connected to each other via the connection faces NS_CS of the sheet pattern. The upper surface NS_US of the sheet pattern and the lower surface NS_BS of the sheet pattern may be connected to each other via a sidewall NS_SW of the sheet pattern.

The connection face NS_CS of the sheet pattern is connected to and in contact with a source/drain pattern 150 to be described in greater detail later. The connection face NS_CS of the sheet pattern may be a boundary between the sheet patterns NS and the source/drain pattern 150.

In FIGS. 3 and 6, a sidewall NS_SW of the sheet pattern is illustrated as a combination of a curved portion and a flat portion. However, one or more example embodiments are not limited thereto. That is, according to one or more example embodiments, a sidewall NS_SW of the sheet pattern may be entirely curved or may be entirely flat.

The third direction D3 may be a direction intersecting the first direction D1 and the second direction D2. For example, the third direction D3 may be a thickness direction of the substrate 100. The first direction D1 may be a direction intersecting the second direction D2.

Although it is illustrated that the sheet patterns NS includes three sheet patterns stacked in the third direction D3, this is intended only for convenience of illustration, and one or more example embodiments are not limited to this example configuration.

The lower pattern BP may be formed by etching a portion of the substrate 100, or may include an epitaxial layer grown from the substrate 100. The lower pattern BP may include silicon or germanium as an elemental semiconductor material. Further, the lower pattern BP may include a compound semiconductor, for example, a group IV-IV compound semiconductor or a group III-V compound semiconductor.

The group IV-IV compound semiconductor may include, for example, but is not limited to, a binary compound including two of carbon (C), silicon (Si), germanium (Ge), and tin (Sn), a ternary compound including three thereof, or a compound obtained by doping a group IV element thereto.

The group III-V compound semiconductor may include, for example, but is not limited to, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

The sheet patterns NS may include one of an element semiconductor material such as silicon or germanium, a group IV-IV compound semiconductor, or a group III-V compound semiconductor. Each one of the sheet patterns NS may include the same material as that of the lower pattern BP, or may include a material different from that of the lower pattern BP.

In the semiconductor device according to one or more example embodiments, the lower pattern BP may be a silicon lower pattern including silicon, while the sheet patterns NS may be a silicon sheet pattern including silicon.

A width in the first direction D1 of the sheet patterns NS may be increased or decreased in proportion to a width in the first direction D1 of the lower pattern BP. For example, the width in the first direction D1 of each of the sheet patterns NS stacked in the third direction D3 may increase and then decrease as the sheet pattern extends away from the lower pattern BP. However, one or more example embodiments are not limited thereto. In one or more example embodiments, the width in the first direction D1 of each of the sheet patterns NS stacked in the third direction D3 may be constant as the sheet pattern extends away from the lower pattern BP.

The field insulating film 105 (see e.g., FIG. 3) may be formed on the substrate 100. The field insulating film 105 may be disposed on a sidewall of the lower pattern BP. The field insulating film 105 may not be disposed on the upper surface BP_US of the lower pattern.

In one example, the field insulating film 105 may cover an entirety of the sidewall of the lower pattern BP. Unlike what is illustrated in the drawings, according to one or more example embodiments, the field insulating film 105 may cover only a portion of the sidewall of the lower pattern BP. In this case, the portion of the lower pattern BP may protrude in the third direction D3 beyond a upper surface of the field insulating film 105.

Each one of the sheet patterns NS may be disposed at a higher vertical level than that of the upper surface of the field insulating film 105. The field insulating film 105 may include, for example, but is not limited to, an oxide film, a nitride film, an oxynitride film, or a combination film thereof. Although the field insulating film 105 is illustrated as being embodied as a single film, this is intended only for convenience of illustration, and one or more example embodiments are not limited thereto.

The plurality of gate structures GS may be disposed on the substrate 100. Each one of the gate structures GS may extend in the second direction D2. The gate structures GS may be spaced apart from each other in the first direction D1. The gate structures GS may be adjacent to each other in the first direction D1.

The gate structures GS may be disposed on the active pattern AP. The gate structures GS may intersect the active pattern AP. The gate structures GS may intersect the lower pattern BP. The gate structures GS may surround each of the sheet patterns NS. The gate structures GS may include, for example, a gate electrode 120 and a gate insulating film 130.

The gate structures GS may include inter gate structures INT_GS1, INT_GS2, and INT_GS3 disposed between sheet patterns NS adjacent to each other in the third direction D3 and between the lower pattern BP and the lowest one of the sheet patterns NS. The inter gate structures INT_GS1, INT_GS2, and INT_GS3 may be disposed between the upper surface BP_US of the lower pattern and the lower surface NS_BS of the lowermost sheet pattern, and between the upper surface NS_US of the sheet pattern and the lower surface NS_BS of the sheet pattern facing each other in the third direction D3.

The number of the inter gate structures INT_GS1, INT_GS2, and INT_GS3 may be proportional to the number of the sheet patterns NS included in the active pattern AP. For example, the number of the inter gate structures INT_GS1, INT_GS2, and INT_GS3 may be equal to the number of the sheet patterns NS. Because the active pattern AP includes the plurality of sheet patterns NS, the gate structures GS may include a plurality of inter gate structures.

The inter gate structures INT_GS1, INT_GS2, and INT_GS3 are in contact with the source/drain pattern 150 to be described in detail later. For example, the inter gate structures INT_GS1, INT_GS2, and INT_GS3 may directly contact the source/drain pattern 150. The inter gate structures INT_GS1, INT_GS2, and INT_GS3 are in contact with the upper surface BP_US of the lower pattern, the upper surface NS_US of the sheet pattern, and the lower surface NS_BS of the sheet pattern.

The following descriptions are made based on one or more example embodiments where the number of the inter gate structures INT_GS1, INT_GS2, and INT_GS3 is three.

The gate structures GS may include the first inter gate structure INT_GS1, the second inter gate structure INT_GS2, and the third inter gate structure INT_GS3. The first inter gate structure INT_GS1, the second inter gate structure INT_GS2, and the third inter gate structure INT_GS3 may be sequentially stacked on top of each other while being disposed on the lower pattern BP.

The third inter gate structure INT_GS3 may be disposed between the lower pattern BP and the sheet patterns NS. The third inter gate structure INT_GS3 may be the lowest one of the inter gate structures INT_GS1, INT_GS2, and INT_GS3. The third inter gate structure INT_GS3 may be in contact with the upper surface BP_US of the lower pattern.

Each of the first inter gate structure INT_GS1 and the second inter gate structure INT_GS2 may be disposed between the sheet patterns NS adjacent to each other in the third direction D3. The first inter gate structure INT_GS1 may be the topmost one among the inter gate structures INT_GS1, INT_GS2, and INT_GS3. The first inter gate structure INT_GS1 may contact the lower surface NS_BS of the topmost sheet pattern. The second inter gate structure INT_GS2 may be disposed between the first inter gate structure INT_GS1 and the third inter gate structure INT_GS3.

Each of the inter gate structures INT_GS1, INT_GS2, and INT_GS3 may include the gate electrode 120 and the gate insulating film 130 provided between the adjacent sheet patterns NS and provided between the lower pattern BP and the lowest one of the sheet patterns NS.

In one or more example embodiments, a width in the first direction D1 of the first inter gate structure INT_GS1 may be equal to a width in the first direction D1 of the second inter gate structure INT_GS2. Further, the width in the first direction D1 of the second inter gate structure INT_GS2 may be equal to a width in the first direction D1 of the third inter gate structure INT_GS3. However, one or more example embodiments are not limited to this configuration.

In the semiconductor device according to one or more example embodiments, the width in the first direction D1 of the second inter gate structure INT_GS2 may be smaller than the width in the first direction D1 of the third inter gate structure INT_GS3.

For reference, a plan view at a level of the second inter gate structure INT_GS2 is illustrated in FIG. 7, according to one or more example embodiments. According to one or more example embodiments, a plan view at a level of each of the first inter gate structure INT_GS1 and the third inter gate structure INT_GS3 may be similar to that of the one or more example embodiments shown in FIG. 7.

The gate electrode 120 may be formed on the lower pattern BP. The gate electrode 120 may intersect the lower pattern BP. The gate electrode 120 may surround the sheet patterns NS.

A portion of the gate electrode 120 may be provided between the adjacent sheet patterns NS and between the lower pattern BP and the lowest one of the sheet patterns NS. When the sheet patterns NS include the first sheet pattern and the second sheet pattern adjacent to each other in the third direction D3, a portion of the gate electrode 120 may be provided between the upper surface NS_US of the first sheet pattern and the lower surface NS_BS of the second sheet pattern facing each other. Further, a portion of the gate electrode 120 may be provided between the upper surface BS_US of the lower pattern and the lower surface NS_BS of the lowermost one of the sheet patterns NS. The first sheet pattern may be the lowermost one of the sheet patterns NS or may not be the lowermost one of the sheet patterns.

The gate electrode 120 may include, but is not limited to, at least one of a metal, a metal alloy, a conductive metal nitride, a metal silicide, a doped semiconductor material, a conductive metal oxide, and a conductive metal oxynitride. The gate electrode 120 may include at least one of, for example, but is not limited to, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. One or more example embodiments are not limited to the above description. The gate electrode 120 may include, but is not limited to, a conductive metal oxide, a conductive metal oxynitride, and the like or may include, but is not limited to, oxidized products of the above-mentioned materials.

The gate electrode 120 may be provided on both opposing sides of the source/drain pattern 150 to be described in greater detail later. The gate structures GS may be provided on both opposing sides in the first direction D1 of the source/drain pattern 150.

For example, according to one or more example embodiments, each of the gate electrodes 120 respectively provided on both opposing sides of the source/drain pattern 150 may be a normal gate electrode used as a gate of a transistor. In another one or more example embodiments, the gate electrode 120 provided on one side of the source/drain pattern 150 may be used as a gate of the transistor, while the gate electrode 120 provided on the other side of the source/drain pattern 150 may be a dummy gate electrode.

The gate insulating film 130 may extend along the upper surface of the field insulating film 105 and the upper surface BP_US of the lower pattern. The gate insulating film 130 may cover the plurality of sheet patterns NS. The gate insulating film 130 may surround the sheet patterns NS. The gate electrode 120 is provided on the gate insulating film 130. The gate insulating film 130 is provided between the gate electrode 120 and the sheet patterns NS.

A portion of the gate insulating film 130 may be provided between the sheet patterns NS adjacent to each other in the third direction D3 and between the lower pattern BP and the lowest one of the sheet patterns NS. When the sheet patterns NS include the first sheet pattern and the second sheet pattern adjacent to each other in the third direction D3, a portion of the gate insulating film 130 may extend along the upper surface NS_US of the first sheet pattern and the lower surface NS_BS of the second sheet pattern facing each other.

The gate insulating film 130 may include a horizontal portion 130_H, a first vertical portion 130_V1, and a second vertical portion 130_V2. The horizontal portion 130_H of the gate insulating film 130 may extend along the upper surface NS_US of the sheet patterns NS and the lower surface NS_BS of the sheet patterns NS. The horizontal portion 130_H of the gate insulating film 130 may extend along the upper surface BP_US of the lower pattern.

The first vertical portion 130_V1 of the gate insulating film 130 may extend along the source/drain pattern 150. The second vertical portion 130_V2 of the gate insulating film 130 may extend along the sidewall NS_SW of the sheet pattern. The horizontal portion 130_H of the gate insulating film 130 and the first vertical portion 130_V1 of the gate insulating film 130 may be included in the inter gate structures INT_GS1, INT_GS2, and INT_GS3.

The gate insulating film 130 may include an interfacial insulating film 131 and a high dielectric constant insulating film 132. The high dielectric constant insulating film 132 may be provided between the interfacial insulating film 131 and the gate electrode 120.

The interfacial insulating film 131 may extend along the upper surface BP_US of the lower pattern BP. The interfacial insulating film 131 may extend along the source/drain pattern 150. The interfacial insulating film 131 may surround the sheet pattems NS. According to one or more example embodiments, the interfacial insulating film 131 may not extend along a sidewall of one of the gate spacers 140 to be described in greater detail later. The interfacial insulating film 131 may be in direct contact with the lower pattern BP, the source/drain pattern 150 and the sheet patterns NS.

The high dielectric constant insulating film 132 may extend along the upper surface of the field insulating film 105 and the upper surface BP_US of the lower pattern BP. The high dielectric constant insulating film 132 may extend along the source/drain pattern 150. The high dielectric constant insulating film 132 may surround the sheet patterns NS. The high dielectric constant insulating film 132 may extend along the sidewall of one of the gate spacers 140 to be described in greater detail later.

The interfacial insulating film 131 may include a horizontal portion 131_H, a first vertical portion 131_V1, and a second vertical portion 131_V2. The high dielectric constant insulating film 132 may include a horizontal portion 132_H, a first vertical portion 132_V1, and a second vertical portion 132_V2.

Each of the horizontal portion 131_H of the interfacial insulating film 131 and the horizontal portion 132_H of the high dielectric constant insulating film 132 may extend along the upper surface NS_US of the sheet patterns NS and the lower surface NS_BS of the sheet patterns NS. Each of the horizontal portion 131_H of the interfacial insulating film 131 and the horizontal portion 132_H of the high dielectric constant insulating film 132 may extend along the upper surface BP_US of the lower pattern BP.

Each of the first vertical portion 131_V1 of the interfacial insulating film 131 and the first vertical portion 132_V1 of the high dielectric constant insulating film 132 may extend along the source/drain pattern 150. Each of the second vertical portion 131V2 of the interfacial insulating film 131 and the second vertical portion 132_V2 of the high dielectric constant insulating film 132 may extend along the sidewall NS_SW of the sheet patterns NS.

The horizontal portion 130_H of the gate insulating film 130 includes the horizontal portion 131_H of the interfacial insulating film 131 and the horizontal portion 132_H of the high dielectric constant insulating film 132. The first vertical portion 130_V1 of the gate insulating film 130 includes the first vertical portion 131_V1 of the interfacial insulating film 131 and the first vertical portion 132_V1 of the high dielectric constant insulating film 132. The second vertical portion 130_V2 of the gate insulating film 130 includes the second vertical portion 131_V2 of the interfacial insulating film 131 and the second vertical portion 132_V2 of the high dielectric constant insulating film 132.

The horizontal portion 131_H of the interfacial insulating film 131, the horizontal portion 132_H of the high dielectric constant insulating film 132, the first vertical portion 131_V1 of the interfacial insulating film 131 and the first vertical portion 132_V1 of the high dielectric constant insulating film 132 may be included in the inter gate structures INT_GS1, INT_GS2, and INT_GS3.

In one or more example embodiments, a dimension t12 in the third direction D3 of the horizontal portion 132_H of the high dielectric constant insulating film 132 may be equal to a dimension t22 in the first direction D1 of the first vertical portion 132_V1 of the high dielectric constant insulating film 132. A dimension t11 in the third direction D3 of the horizontal portion 131_H of the interfacial insulating film 131 is smaller than a dimension t21 in the first direction D1 of the first vertical portion 131_V1 of the interfacial insulating film 131. That is, a dimension t1 in the third direction D3 of the horizontal portion 130H of the gate insulating film 130 is smaller than a dimension t2 in the first direction D1 of the first vertical portion 130_V1 of the gate insulating film 130.

The dimension 112 in the third direction D3 of the horizontal portion 132_H of the high dielectric constant insulating film 132 may be equal to a dimension t32 in the second direction D2 of the second vertical portion 132_V2 of the high dielectric constant insulating film 132. The dimension tl1 in the third direction D3 of the horizontal portion 131_H of the interfacial insulating film 131 may be equal to a dimension t31 in the second direction D2 of the second vertical portion 131_V2 of the interfacial insulating film 131. The dimension t1 in the third direction D3 of the horizontal portion 130H of the gate insulating film 130 may be equal to a dimension t3 in the second direction D2 of the second vertical portion 130_V2 of the gate insulating film 130.

The first vertical portion 131_V1 of the interfacial insulating film 131 may be formed to have a uniform dimension along the source/drain pattern 150.

When the dimension t21 of the first vertical portion 131_V1 of the interfacial insulating film 131 is greater than the dimension t11 of the horizontal portion 131_H of the interfacial insulating film 131, leakage current between the gate electrode 120 and the source/drain pattern 150 may be effectively reduced.

The first vertical portion 131_V1 of the interfacial insulating film 131 may include a first area R1 and a second area R2. The first area R1 may be in contact with source/drain pattern 150. The second area R2 may be provided between the first area R1 and the gate electrode 120. The second area R2 may be in contact with the high dielectric constant insulating film 132.

The interfacial insulating film 131 may include an element “A” other than silicon. The element “A” may be an element substituted with hydrogen in a manufacturing process to be described in greater detail later. For example, the element “A” may be any one of, but is not limited to, carbon (C), boron (B), phosphorus (P), and nitrogen (N). However, one or more example embodiments are not limited thereto.

A concentration of the element “A” in the first area R1 of the interfacial insulating film 131 may be different from a concentration of the element A in the second area R2 thereof. The concentration of the element “A” in the first area R1 may be higher than the concentration of the element “A” in the second area R2. For example, the concentration of the element “A” may be kept constant in the first area R1 and then rapidly decrease in the second area R2. However, unlike what is illustrated in the drawings, according to one or more example embodiments, the concentration of the element “A” in each of the first area R1 and the second area R2 may gradually decrease as each of the first area R1 and the second area R2 extends away from the source/drain pattern 150.

The source/drain pattern 150 to be described in greater detail later may include a third area R3. Specifically, a first liner film 151 of the source/drain pattern 150 may include the third area R3. The third area R3 may contact the first area R1 of the first vertical portion 131_V1 of the interfacial insulating film 131. The third area R3 may include the element “A”. The element “A” of the third area R3 is the same as the element “A” of the first area R1.

A concentration of the element “A” in the third area R3 may be higher than the concentration of the element “A” in the first area R1. For example, the concentration of the element “A” may be kept constant in the third area R3 and then rapidly decrease in the first area R1. However, unlike what is illustrated in the drawings, according to one or more example embodiments, the concentration of the element “A” at a position may gradually decrease as the position is displaced in a direction from the third area R3 to the first area R1 to the second area R2.

In one or more example embodiments, the concentration of the element “A” in the second area R2 of the first vertical portion 131_V1 of the interfacial insulating film 131 may be close to zero. In this regard, “a concentration in the second area R2 is 0” may mean that the second area R2 of the first vertical portion 131_V1 of the interfacial insulating film 131 does not contain the element “A”. Alternatively, “the concentration in the second area R2 is 0” may mean that the second area R2 of the first vertical portion 131_V1 of the interfacial insulating film 131 contains the element “A” at a concentration lower than a concentration corresponding to a detection limit of detection equipment.

Referring to FIG. 2 and FIG. 7, a plurality of gate spacers 140 may be provided on the interfacial insulating film 131. In a plan view, the gate spacers 140 may be spaced apart from each other in the second direction D2. The interfacial insulating film 131 may be provided between the gate spacers 140, which are spaced from each other. In other words, the interfacial insulating film 131 may overlap with the gate spacers 140 in the second direction D2.

The first area R1 of the interfacial insulating film 131 may have a first width W1 in the first direction D1. The interfacial insulating film 131 may have a second width W2 in the first direction D1. The second width W2 may correspond to the dimension t21 in the first direction D1 of the first vertical portion 131_V1 of the interfacial insulating film 131.

The high dielectric constant insulating film 132 may include at least one of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to one or more example embodiments may include a negative capacitance (NC) FET using a negative capacitor. In one or more example embodiments, the high dielectric constant insulating film 132 may include a ferroelectric material film having ferroelectric properties. In another one or more example embodiments, the high dielectric constant insulating film 132 may include a ferroelectric material film having ferroelectric properties and a paraelectric material film having paraelectric properties.

The ferroelectric material film may have negative capacitance, and the paraelectric material film may have positive capacitance. For example, when two or more capacitors are connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, but is not limited to, at least one of hafnium oxide, hafnium zirconium oxide, barium strontium titanium oxide, barium titanium oxide, and lead zirconium titanium oxide. In this connection, in one or more example embodiments, hafnium zirconium oxide may refer to a material obtained by doping hafnium oxide with zirconium (Zr). In another one or more example embodiments, hafnium zirconium oxide may refer to a compound of hafnium (Hf), zirconium (Zr), and oxygen (O).

The ferroelectric material film may further contain doped dopants. For example, the dopants may include, but are not limited to, at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, but is not limited to, for example, at least one of gadolinium (Gd), silicon (Si), zirconium (Zr), aluminum (Al), and yttrium (Y).

When the dopant is aluminum (Al), the ferroelectric material film may include about 3 to about 8 at % (atomic %) of aluminum. In this connection, a content of the dopant may be a content of aluminum based on a sum of hafnium and aluminum.

When the dopant is silicon (Si), the ferroelectric material film may include about 2 to about 10 at % of silicon. When the dopant is yttrium (Y), the ferroelectric material film may include about 2 to about 10 at % yttrium. When the dopant is gadolinium (Gd), the ferroelectric material film may include about 1 to about 7 at % gadolinium. When the dopant is zirconium (Zr), the ferroelectric material film may include about 50 to about 80 at % zirconium.

The paraelectric material film may have paraelectric properties. The paraelectric material film may include, for example, at least one of silicon oxide and metal oxide having a high dielectric constant. The metal oxide contained in the paraelectric material film may include, but is not limited to, for example, at least one of hafnium oxide, zirconium oxide and aluminum oxide. However, one or more example embodiments are not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, one or more example embodiments are not limited thereto. Because a critical thickness exhibiting the ferroelectric properties may be vary based on a type of the ferroelectric material, the thickness of the ferroelectric material film may vary depending on the type of the ferroelectric material.

In one or more example embodiments, the high dielectric constant insulating film 132 may include one ferroelectric material film. In another one or more example embodiments, the high dielectric constant insulating film 132 may include a plurality of ferroelectric material films spaced apart from each other. The high dielectric constant insulating film 132 may have a stacked film structure in which a plurality of ferroelectric material films and a plurality of paraelectric material films are alternately stacked on top of each other.

One of the gate spacers 140 may be provided on a sidewall of the gate electrode 120. According to one or more example embodiments, the gate spacers 140 may not be provided between the lower pattern BP and the lowest one of the sheet patterns NS, and between the sheet patterns NS adjacent to each other in the third direction D3.

The gate spacers 140 may include, but are not limited to, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. Although the gate spacers 140 are illustrated as being embodied as a single film, this is intended only for convenience of illustration, and one or more example embodiments are not limited thereto.

The gate capping pattern 145 may be provided on the gate structures GS and the gate spacers 140. A upper surface of the gate capping pattern 145 may be coplanar with a upper surface of the interlayer insulating film 190. Unlike what is illustrated in the drawings, according to one or more example embodiments, the gate capping pattern 145 may be provided between the gate spacers 140.

The gate capping pattern 145 may include, for example, at least one of silicon nitride (SiN), silicon oxynitride (SiON), silicon carbonitride (SiCN), silicon oxycarbonitride (SiOCN), or combinations thereof. The gate capping pattern 145 may include a material having an etching selectivity to a material of the interlayer insulating film 190.

The source/drain pattern 150 may be formed on the active pattern AP. The source/drain pattern 150 may be provided on the lower pattern BP The source/drain pattern 150 may be connected to the sheet patterns NS. The source/drain pattern 150 may be in contact with the sheet patterns NS.

The source/drain pattern 150 may be provided on a side face of the gate structures GS. The source/drain pattern 150 may be provided between the gate structures GS adjacent to each other in the first direction D1. For example, the source/drain pattern 150 may be provided on both opposing sides of the gate structures GS. Unlike what is illustrated in the drawings, according to one or more example embodiments, the source/drain pattern 150 may be provided on one side of the gate structures GS and may not be provided on the other side of the gate structures GS.

The source/drain pattern 150 may be included in a source/drain of a transistor using the sheet patterns NS as a channel area thereof.

The source/drain pattern 150 may be provided within a source/drain recess 150R. The source/drain recess 150R extends in the third direction D3. The source/drain recess 150R may be defined between the gate structures GS adjacent to each other in the first direction D1.

A lower surface of the source/drain recess 150R may be defined by the lower pattern BP. A sidewall of the source/drain recess 150R may be defined by the sheet patterns NS and the inter gate structures INT_GS1, INT_GS2, and INT_GS3. A sidewall of each of the inter gate structures INT_GS1, INT_GS2, and INT_GS3 may be defined by the gate insulating film 130 of each of the inter gate structures INT_GS1, INT_GS2, and INT_GS3.

In an area between the lowest one of the sheet patterns NS and the lower pattern BP, a boundary between the gate insulating film 130 and the lower pattern BP may be the upper surface BP_US of the lower pattern BP. In other words, the upper surface BP_US of the lower pattern BP may be a boundary between the third inter gate structure INT_GS3 as the lowest inter gate structure and the lower pattern BP. A vertical level of the lower surface of the source/drain recess 150R may be lower than that of the upper surface BP_US of the lower pattern BP.

The source/drain pattern 150 may be provided within the source/drain recess 150R. The source/drain pattern 150 may fill the source/drain recess 150R.

The source/drain pattern 150 may contact the sheet patterns NS and the lower pattern BP Because the gate spacers 140 are not provided between the adjacent sheet patterns NS, the interfacial insulating film 131 is in contact with the source/drain pattern 150.

The source/drain pattern 150 may include an epitaxial pattern. The source/drain pattern 150 may include a semiconductor material.

The source/drain pattern 150 may include, but are not limited to, for example, silicon or germanium, as an elemental semiconductor material. Further, source/drain pattern 150 may include, but are not limited to, for example, at least one of a binary compound including two of carbon (C), silicon (Si), germanium (Ge), and tin (Sn), a ternary compound including three of carbon (C), silicon (Si), germanium (Ge), and tin (Sn), or a compound obtained by doping a group IV element thereto. For example, the source/drain pattern 150 may include, but is not limited to, silicon, silicon-germanium, germanium, silicon carbide, or the like.

The source/drain pattern 150 may contain impurities doped into the semiconductor material. The doped impurities may include, but is not limited to, at least one of boron (B), phosphorus (P), carbon (C), arsenic (As), antimony (Sb), bismuth (Bi), or oxygen (O).

The source/drain pattern 150 may include the first liner film 151, a second liner film 152, and a filling film 153.

The first liner film 151 may be formed along the sidewall of the source/drain recess 150R and the lower surface of the source/drain recess 150R. A portion of the first liner film 151 formed along the sidewall of the source/drain recess 150R may be in direct contact with the inter gate structures INT1_GS1, INT2_GS1, and INT3_GS1 and the sheet patterns NS. A portion of the first liner film 151 formed along the lower surface of the source/drain recess 150R may be in contact with the lower pattern BP.

The first liner film 151 may contain germanium (Ge). The first liner film 151 may include the third area R3. The third area R3 may contact the first area R1 of the interfacial insulating film 131. The third area R3 may contain the element “A”. In this regard, the element “A” is the same as the element “A” in the first area R1.

The first liner film 151 is illustrated as being embodied as a single film. However, one or more example embodiments are not limited thereto. For example, the first liner film 151 may comprise a stack of a film including the element and a film free of the element “A”.

Referring to FIG. 2, FIG. 7 and FIG. 8, a germanium (Ge) concentration in the first liner film 151 and the first area R1 has been described.

At an interface between the first liner film 151 and the interfacial insulating film 131, the concentration of germanium (Ge) may change rapidly. For example, the concentration of germanium (Ge) may be the highest at an interface between the first area R1 of the interfacial insulating film 131 and the first liner film 151, and may decrease as a position moves away from the interface. The concentration of germanium (Ge) in the first liner film 151 may decrease as the first liner film 151 extends away from the interfacial insulating film 131.

The second liner film 152 may be formed along the first liner film 151. The second liner film 152 may be in direct contact with the first liner film 151. The second liner film 152 may contain germanium (Ge). The germanium (Ge) concentration in the second liner film 152 may be higher than a concentration of germanium (Ge) in the first liner film 151.

The filling film 153 may be formed on the second liner film 152. The filling film 153 may fill a remaining portion of the source/drain recess 150R after the first liner film 151 and the second liner film 152 have filled the source/drain recess 150R. The filling film 153 may contain germanium (Ge). A concentration of germanium (Ge) in the filling film 153 may be higher than the concentration of germanium (Ge) in the second liner film 152.

The etch stop film 185 may extend along an outer sidewall 140_OSW of the gate spacers 140 and a profile of the source/drain pattern 150. According to one or more example embodiments, the etch stop film 185 may be provided on the upper surface of the field insulating film 105.

The etch stop film 185 may include a material having an etch selectivity to a material of the interlayer insulating film 190 to be described in greater detail later. The etch stop film 185 may include, but is not limited to, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or combinations thereof.

The interlayer insulating film 190 may be provided on the etch stop film 185. The interlayer insulating film 190 may be provided on the source/drain pattern 150. According to one or more example embodiments, the interlayer insulating film 190 may not cover an upper surface of the gate capping pattern 145. For example, a upper surface of the interlayer insulating film 190 may be coplanar with a upper surface of the gate capping pattern 145.

The interlayer insulating film 190 may include, but is not limited to, for example, at least one of silicon oxide, silicon nitride, silicon oxynitride, or a low dielectric constant material. The low dielectric constant material may include, but is not limited to, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, one or more example embodiments are not limited thereto.

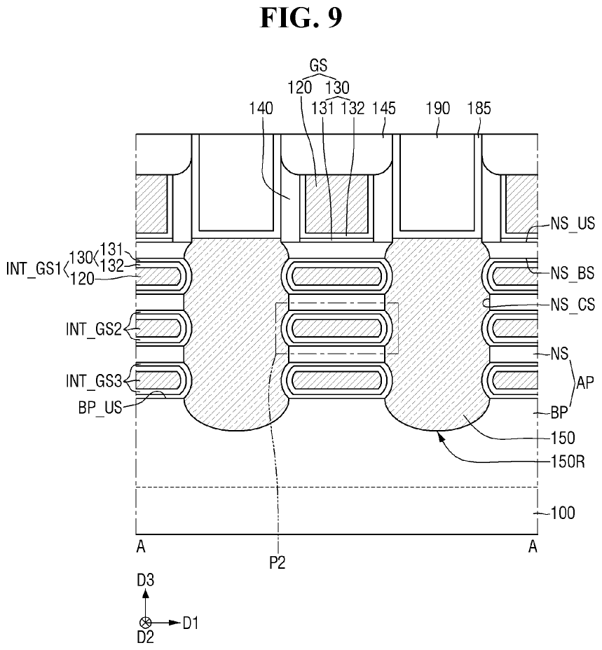

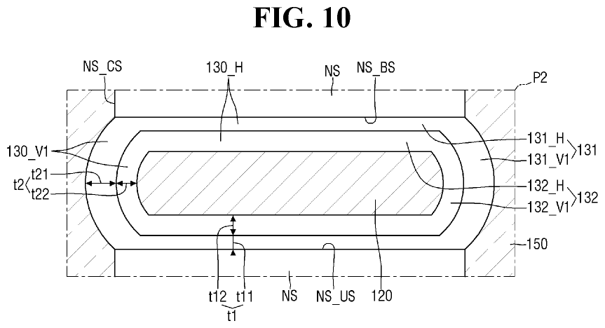

FIGS. 9 and 10 are diagrams for illustrating a semiconductor device according to one or more example embodiments. For convenience of description, the following descriptions are based on differences thereof from one or more example embodiments as described with reference to FIGS. 1, 2, 3, 4, 5, 6, 7 and 8.

Referring to FIG. 9 and FIG. 10, in the semiconductor device according to one or more example embodiments, each of the inter gate structures INT_GS1, INT_GS2, and INT_GS3 may protrude toward the source/drain pattern 150 in the first direction D1 beyond the connection face NS_CS of each of at least one of the sheet patterns NS.

For example, a portion of the first inter gate structure INT_GS1 and a portion of the second inter gate structure INT_GS2 may protrude toward the source/drain pattern 150 beyond the connection face NS_CS of the one of the sheet patterns NS provided between the first inter gate structure INT_GS1 and the second inter gate structure INT_GS2.

A portion of the second inter gate structure INT_GS2 and a portion of the third inter gate structure INT_GS3 may protrude toward the source/drain pattern 150 beyond the connection face NS_CS of the sheet patterns NS provided between the second inter gate structure INT_GS2 and the third inter gate structure INT_GS3.

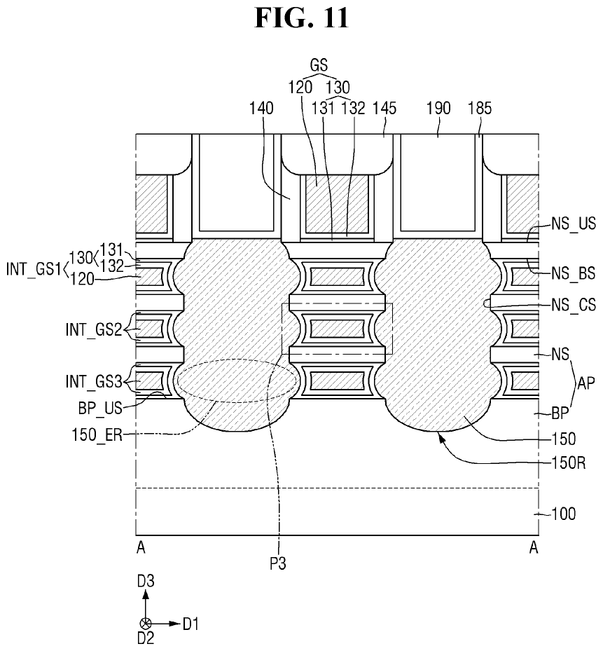

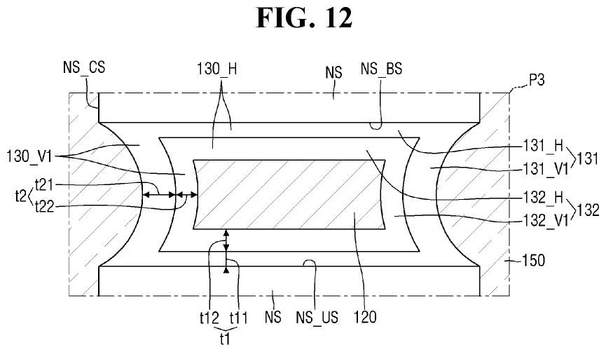

FIG. 11 and FIG. 12 are diagrams for illustrating a semiconductor device according to one or more example embodiments. For convenience of description, following descriptions are based on differences thereof from one or more example embodiments described with reference to FIGS. 1, 2, 3, 4, 5, 6, 7 and 8.

Referring to FIGS. 11 and 12, in the semiconductor device according to one or more example embodiments, the source/drain pattern 150 may include a plurality of width extension areas 150_ER.

A sidewall of the source/drain pattern 150 may have a wavy shape. Each of the width extension areas 150_ER of the source/drain pattern 150 may be positioned above the upper surface BP_US of the lower pattern BP.

The width extension areas 150_ER of the source/drain pattern 150 may be defined between sheet patterns NS adjacent to each other in the third direction D3. The width extension areas 150_ER of the source/drain pattern 150 may be defined between the lower pattern BP and the lowest one of the sheet patterns NS. The width extension areas 150_ER of the source/drain pattern 150 may extend into an area between sheet patterns NS adjacent to each other in the third direction D3.

In other words, the width extension areas 150_ER of the source/drain pattern 150 may be provided between the adjacent sheet patterns NS and may be defined between the inter gate structures adjacent to each other in the first direction D1. The width extension areas 150_ER of the source/drain pattern 150 may be provided between the lowest one of the sheet patterns NS and the lower pattern BP, and may be defined between the third inter gate structures INT_GS3 adjacent to each other in the first direction D1.

The width extension areas 150_ER of the source/drain pattern 150 may include a first portion whose a width in the first direction D1 increases as the first portion extends away from the upper surface BP_US of the lower pattern BP, and a second portion whose a width in the first direction D1 decreases as the second portion extends away from the upper surface BP_US of the lower pattern BP. For example, as the width extension areas 150_ER of the source/drain pattern 150 extends away from the upper surface BP_US of the lower pattern BP, the width of the width extension areas 150_ER of the source/drain pattern 150 may increase and then decrease.

A point in each of the width extension areas 150_ER of the source/drain pattern 150 at which a width of each of the width extension areas 150_ER of the source/drain pattern 150 is the largest is positioned between the lowest one of the sheet patterns NS and the lower pattern BP, or between the sheet patterns NS adjacent to each other in the third direction D3.

A sidewall of each of the inter gate structures INT_GS1, INT_GS2, and INT_GS3 as a boundary between each of the inter gate structures INT_GS1, INT_GS2, and INT_GS3 and the source/drain pattern 150 may be a concave face.

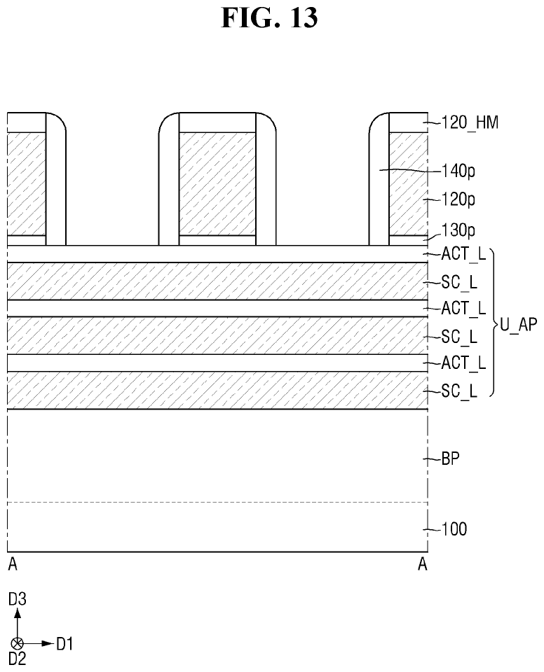

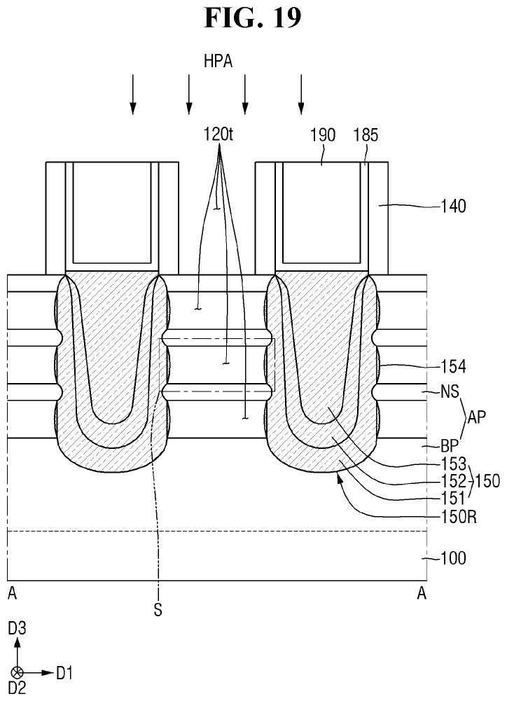

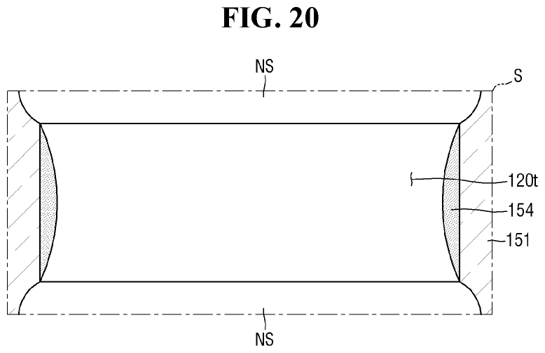

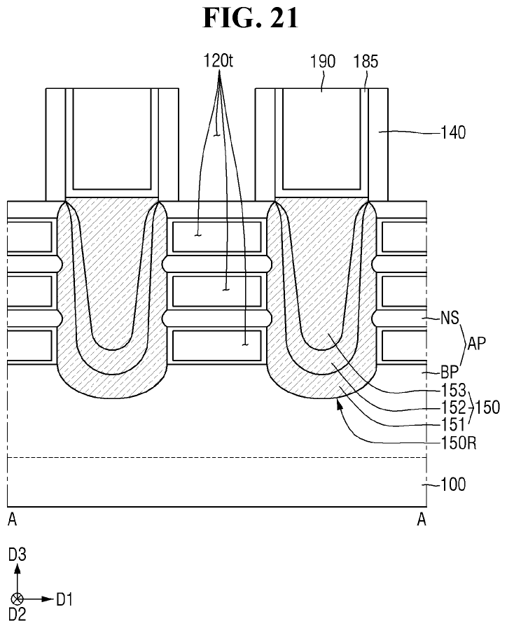

FIGS. 13, 14, 15, 16, 17, 18, 19, 20 and 21 are diagrams of intermediate structures corresponding to intermediate steps for illustrating a method for manufacturing a semiconductor device according to one or more example embodiments. For reference, FIG. 21 and FIG. 13 may be cross-sectional drawings cut along the line A-A in FIG. 1, according to one or more example embodiments. FIG. 20 is an enlarged view of an area “S” of FIG. 19. Hereinafter, a manufacturing method according to one or more example embodiments is described based on a cross-sectional view.

Referring to one or more example embodiments shown in FIG. 13, the lower pattern BP and an upper pattern structure U_AP may be formed on the substrate 100.

The upper pattern structure U_AP may be provided on the lower pattern BP. The upper pattern structure U_AP may include sacrificial patterns SC_L and active patterns ACT_L alternately stacked on top of each other and provided on the lower pattern BP. For example, the sacrificial pattern SC_L may include a silicon-germanium layer. The active pattern ACT_L may include a silicon film.

Subsequently, a dummy gate insulating film 130p, a dummy gate electrode 120p, and a dummy gate capping film 120_HM may be formed on the upper pattern structure U_AP. The dummy gate insulating film 130p may include, for example, silicon oxide. However, one or more example embodiments are not limited thereto. The dummy gate electrode 120p may include, but is not limited to, polysilicon. The dummy gate capping film 120_HM may include, for example, silicon nitride. However, one or more example embodiments are not limited thereto.

A pre-gate spacer 140p may be formed on a sidewall of the dummy gate electrode 120p.

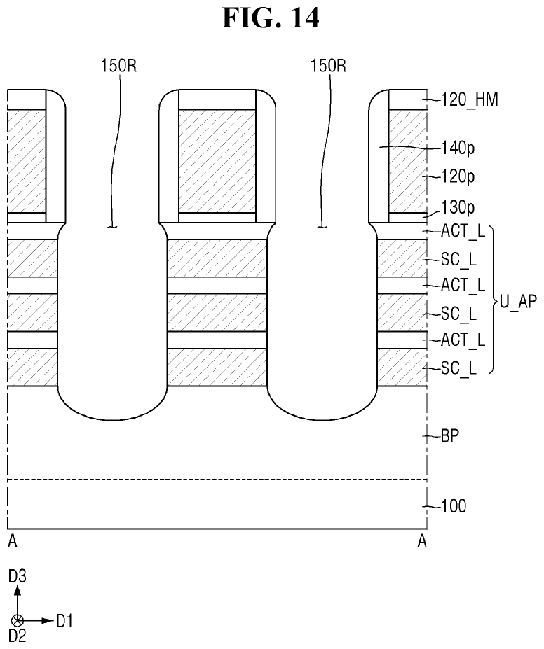

Referring to one or more example embodiments shown in FIG. 14, the source/drain recess 150R may be formed in the upper pattern structure U_AP using the dummy gate electrode 120p as a mask.

A portion of the source/drain recess 150R may be formed in the lower pattern BP.

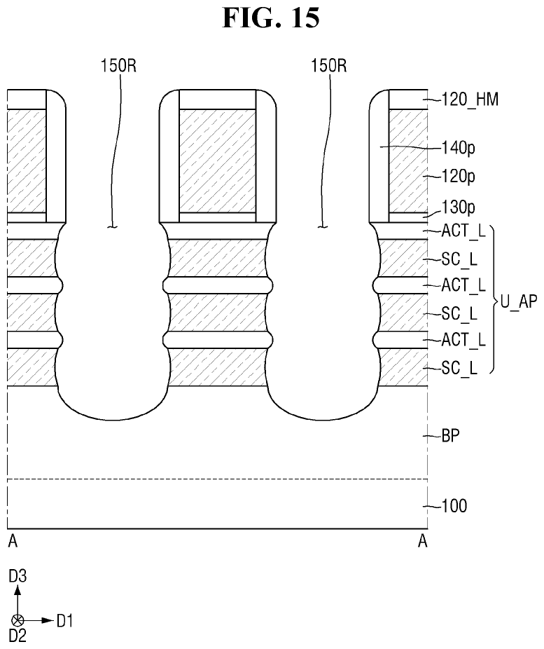

Referring to one or more example embodiments shown in FIG. 15, after the source/drain recess 150R of FIG. 14 has been formed, the sacrificial pattern SC_L exposed through the source/drain recess 150R may be additionally and partially etched. Thus, a sidewall of the source/drain recess 150R may have a wavy shape. However, a scheme of manufacturing the source/drain recess 150R is not limited to the above-described manner.

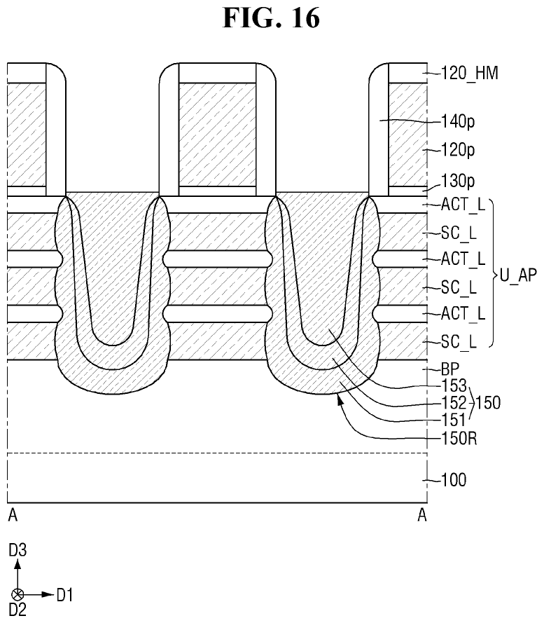

Referring to one or more example embodiments shown in FIG. 16, the source/drain pattern 150 may be formed in the source/drain recess 150R.

The source/drain pattern 150 may be formed on the lower pattern BP. The first liner film 151 may be formed along the sidewall and the lower surface of the source/drain recess 150R. Accordingly, the second liner film 152 and the filling film 153 may be sequentially formed to constitute the source/drain pattern 150. The source/drain pattern 150 may directly contact the sacrificial pattern SC_L and the active pattern ACT_L. Each of the first liner film 151, the second liner film 152, and the filling film 153 may be formed using an epitaxial growth method.

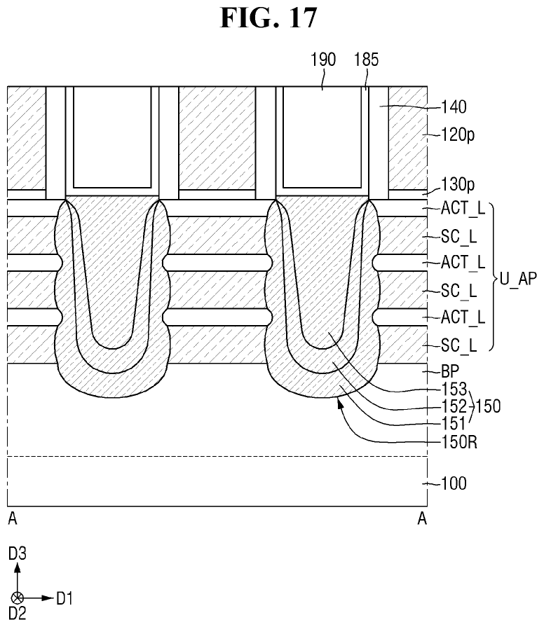

Referring to one or more example embodiments shown in FIG. 17, the etch stop film 185 and the interlayer insulating film 190 are sequentially formed on the source/drain pattern 150.

Next, a portion of the interlayer insulating film 190, a portion of the etch stop film 185, and the dummy gate capping film 120_HM are removed to expose a upper surface of the dummy gate electrode 120p. While the upper surface of the dummy gate electrode 120p is exposed, the gate spacers 140 may be formed.

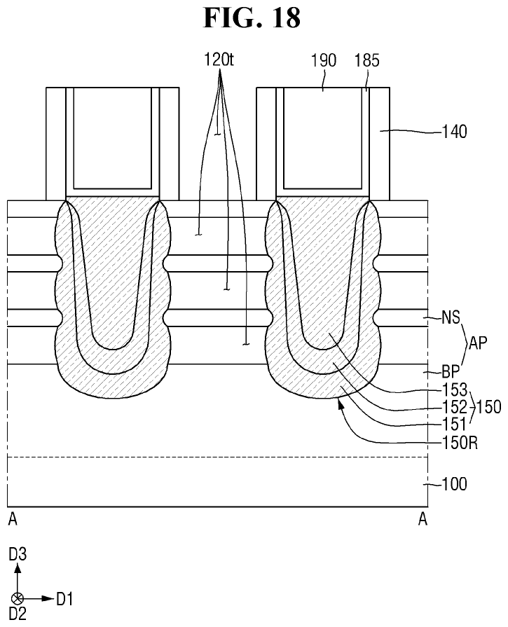

Referring to one or more example embodiments shown in FIG. 18, the dummy gate insulating film 130p and the dummy gate electrode 120p may be removed such that a portion of the upper pattern structure U_AP between the gate spacers 140 may be exposed.

Then, the sacrificial pattern SC_L may be removed such that the sheet patterns NS may be formed. Thus, a gate trench 120t is formed between the gate spacers 140.

Further, the active pattern AP including the lower pattern BP and the sheet patterns NS is formed.

Referring to one or more example embodiments shown in FIGS. 19 and 20, a plasma treatment process may be performed on the gate trench 120t. The plasma treatment process may comprise, for example, a hydrogen plasma anneal (HPA) process. A portion of the source/drain pattern 150 exposed through the gate trench 120t may constitute a growth area 154. Specifically, a portion of the first liner film 151 may be formed as the growth area 154. A concentration of the element “A” in the growth area 154 may be lower than a concentration of the element “A” in the first liner film 151. A concentration of hydrogen (H) in the growth area 154 may be higher than a concentration of hydrogen (H) in the first liner film 151. Although a boundary face between the growth area 154 and the first liner film 151 is illustrated as a straight line, one or more example embodiments are not limited thereto. For example, the boundary face may be a combination of a straight line and a curved line.

Referring to one or more example embodiments shown in FIG. 21, the interfacial insulating film 131 may be formed along the upper surface and the lower surface of the sheet patterns NS exposed through the gate trench 120t.

The interfacial insulating film 131 may be formed along a portion of the source/drain pattern 150 exposed through the gate trench 120t. The growth area 154 may be oxidized to form the interfacial insulating film 131. A dimension in the third direction D3 of a portion of the interfacial insulating film 131 extending along the source/drain pattern 150 is larger than a dimension in the third direction D3 of a portion of the interfacial insulating film 131 extending along the upper surface and the lower surface of the sheet patterns NS.

Subsequently, referring to FIG. 2, the high dielectric constant insulating film 132 and the gate electrode 120 may be formed in the gate trench 120t. Further, the gate capping pattern 145 may be formed on the high dielectric constant insulating film 132, the gate electrode 120 and the gate spacers 140.

While one or more example embodiments have been particularly shown and described above, it will be apparent to those skilled in the art that many variations and modifications may be made to one or more example embodiments without substantially departing from the spirit and scope of the following claims. Therefore, the one or more example embodiments described above are used in a generic and descriptive sense only and not for purposes of limitation.

What is claimed is:

1. A semiconductor device comprising:
an active pattern comprising:
a lower pattern extending in a first direction; and
a plurality of sheet patterns spaced apart from the lower pattern in a second direction perpendicular to an upper surface of the lower pattern, each of the plurality of sheet patterns comprising an upper surface and a lower surface opposite to each other in the second direction;
a gate structure provided on the lower pattern, and comprising a gate electrode and a gate insulating film, wherein the gate electrode and the gate insulating film are around the plurality of sheet patterns; and
a source/drain pattern provided on at least one side of the gate structure,
wherein the gate structure comprises a plurality of inter gate structures provided between the lower pattern and the plurality of sheet patterns and between adjacent sheet patterns of the plurality of sheet patterns,
wherein the plurality of inter gate structures contact the source/drain pattern,
wherein the gate insulating film comprises an interfacial insulating film,
wherein the interfacial insulating film comprises:
a first vertical portion extending along the source/drain pattern; and
a horizontal portion extending along the upper surface of each of the plurality of sheet patterns, and along the lower surface of each of the plurality of sheet patterns,
wherein a first dimension in a third direction of the first vertical portion of the interfacial insulating film is greater than a second dimension in the second direction of the horizontal portion of the interfacial insulating film,
wherein the first vertical portion comprises:
a first area in contact with the source/drain pattern; and
a second area provided between the first area and the gate electrode,
wherein the interfacial insulating film comprises a first element other than silicon, and
wherein a first concentration of the first element in the first area is greater than a second concentration of the first element in the second area.

2. The semiconductor device of claim 1, wherein the source/drain pattern comprises a third area contacting the interfacial insulating film,
wherein the third area comprises the first element, and
wherein a third concentration of the first element in the third area is different from the first concentration of the first element in the first area.

3. The semiconductor device of claim 2, wherein the third concentration of the first element in the third area is greater than the first concentration of the first element in the first area.

4. The semiconductor device of claim 1, wherein the second concentration of the first element in the second area is equal to a fourth concentration of the first element in the horizontal portion.

5. The semiconductor device of claim 1, wherein the first element comprises one of carbon (C), boron (B), phosphorus (P) or nitrogen (N).

6. The semiconductor device of claim 1, wherein each of the plurality of sheet patterns comprises a sidewall connecting the upper surface of each of the plurality of sheet patterns to the lower surface of each of the plurality of sheet patterns,
wherein the interfacial insulating film comprises a second vertical portion extending along the sidewall of the respective one of the plurality of sheet patterns, and
wherein a third concentration of the first element in the first vertical portion is greater than a fourth concentration of the first element in the second vertical portion.

7. The semiconductor device of claim 1, wherein each sheet pattern of the plurality of sheet patterns comprises a sidewall connecting the upper surface of the sheet pattern to the lower surface of the sheet pattern,
wherein the interfacial insulating film comprises a second vertical portion extending along the sidewall of the sheet pattern, and
wherein the second dimension in the second direction of the horizontal portion is equal to a third dimension in the first direction of the second vertical portion.

8. The semiconductor device of claim 1, wherein each of the plurality of inter gate structures further comprises a high dielectric constant insulating film provided between the gate electrode and the interfacial insulating film.

9. The semiconductor device of claim 1, wherein the plurality of inter gate structures comprises:
a first inter gate structure; and
a second inter gate structure,
wherein the plurality of sheet patterns comprises a first sheet pattern provided between the first inter gate structure and the second inter gate structure,
wherein the first sheet pattern comprises a boundary surface contacting the source/drain pattern, and
wherein each of a portion of the first inter gate structure and a portion of the second inter gate structure protrudes toward the source/drain pattern.

10. The semiconductor device of claim 1, wherein the source/drain pattern comprises a plurality of width extension areas, and
wherein a width in the third direction of each of the width extension areas increases and then decreases as each respective one of the width extension areas extends away from the upper surface of the lower pattern.

11. A semiconductor device comprising:
an active pattern comprising:
a lower pattern extending in a first direction; and
a plurality of sheet patterns spaced apart from the lower pattern in a second direction perpendicular to an upper surface of the lower pattern;
a gate structure provided on the lower pattern and extending in a third direction perpendicular to the first direction, the gate structure comprising:
a gate electrode around the plurality of sheet patterns; and
a gate insulating film provided on the gate electrode,
a plurality of gate spacers provided on the gate insulating film and spaced apart from each other in the third direction; and
a source/drain pattern provided between the plurality of gate spacers and contacting each of the plurality of sheet patterns and the gate insulating film,
wherein the gate insulating film comprises an interfacial insulating film,
wherein the interfacial insulating film comprises:
a first area contacting the source/drain pattern; and
a second area provided between the first area and the gate electrode,
wherein the interfacial insulating film comprises a first element other than silicon, and
wherein a first concentration of the first element in the first area is different from a second concentration of the first element in the second area.

12. The semiconductor device of claim 11, wherein the first concentration of the first element in the first area is greater than the second concentration of the first element in the second area.

13. The semiconductor device of claim 11, wherein the interfacial insulating film overlaps the plurality of gate spacers in the third direction.

14. The semiconductor device of claim 11, wherein the source/drain pattern comprises:
a first liner film contacting the interfacial insulating film and the plurality of sheet patterns;
a second liner film provided on the first liner film; and
a filling film provided on the second liner film.

15. The semiconductor device of claim 14, wherein a concentration of germanium (Ge) in the first liner film decreases as the first liner film extends away from the gate insulating film.

16. The semiconductor device of claim 11, wherein the first element comprises one of carbon (C), boron (B), phosphorus (P), or nitrogen N.

17. The semiconductor device of claim 11, wherein the gate insulating film further comprises a high dielectric constant insulating film provided between the gate electrode and the interfacial insulating film.

18. A method for manufacturing a semiconductor device, the method comprising:
providing a substrate;
forming, on the substrate, an upper pattern structure in which a plurality of sacrificial films and a plurality of active films are alternately stacked;
forming a dummy gate electrode on the upper pattern structure;
forming a source/drain recess in the upper pattern structure using the dummy gate electrode as a mask;
etching a portion of each of the plurality of sacrificial films exposed by the source/drain recess;
forming a source/drain pattern filling the source/drain recess;
removing the plurality of sacrificial films to form a gate trench and a plurality of sheet patterns, wherein a portion of the source/drain pattern is exposed by the gate trench;
performing a plasma processing process to form a growth area in the portion of the source/drain pattern exposed by the gate trench; and
forming an interfacial insulating film in the gate trench,
wherein the interfacial insulating film comprises:
a vertical portion contacting the source/drain pattern; and
a horizontal portion extending along an upper surface of each of the plurality of sheet patterns and along a lower surface of the plurality of sheet patterns, and
wherein a first dimension in a vertical direction of the vertical portion is greater than a second dimension in the vertical direction of the horizontal portion.

19. The method of claim 18, wherein the forming the interfacial insulating film in the gate trench comprises:
oxidizing the growth area to form the interfacial insulating film; and
at a same time as the oxidizing the growth area, forming a gate insulating film on the plurality of sheet patterns.

20. The semiconductor device of claim 18, wherein the vertical portion comprises:
a first area contacting the source/drain pattern; and
a second area provided between the first area and the dummy gate electrode,
wherein the interfacial insulating film comprises a first element other than silicon, and
wherein a first concentration of the first element in the first area is greater than a second concentration of the first element in the second area.
